(19) United States
(12) Patent Application Publication
(10) Pub. No.: US 2004/0069983 A1
(43) Pub. Date: Apr. 15, 2004

(54) High-efficiency light emitting diode and method for manufacturing the same

(75) Inventors: Jae-Hee Cho, Kyungki-do (KR); Cheol-Soo Sone, Kyungki-do (KR); Young-Gu Jin, Kyungki-do (KR)

Correspondence Address: BURNS DOANE SWECKER & MATHIS L L P, POST OFFICE BOX 1404, ALEXANDRIA, VA, 22313-1404, US

(73) Assignee: Samsung Electro-mechanics Co., Ltd., Suwon-City (KR)

(21) Appl. No.: 10/448,143

(22) Filed: May 30, 2003

(30) Foreign Application Priority Data
Oct. 11, 2002 (KR) 2002-62116

(51) Int. Cl. H01L 29/06

(52) U.S. Cl. 257/10

(57) ABSTRACT

Provided is a light emitting diode and a method of fabricating the light emitting diode. The light emitting diode includes a substrate, an n-type compound semiconductor layer which is formed on the substrate, an active layer which is formed on the n-type compound semiconductor layer, a p-type compound semiconductor layer which is formed on the active layer, an n-type electrode which contacts the n-type compound semiconductor layer, and a p-type electrode which contacts the p-type compound semiconductor layer. Here, a surface of the active layer from which the light is emitted is a continuous curved surface. Thus, the light emission rate of the active layer can be much higher than an active layer in the conventional light emitting diode. As a result, the light which is estimated to be emitted from the light emitting diode increases, and the light is uniformly emitted in all directions. In addition, the method of the present invention is advantageous in that it is not necessary to add a separate process for forming the wave shape of the active layer.

### BACKGROUND OF THE INVENTION

This application claims priority from Korean Patent Application No. 2002-62116, filed on Oct. 11, 2002, in the Korean Intellectual Property Office, the disclosure of which is incorporated herein in its entirety by reference.

1. Field of the Invention

The present invention relates to the field of light emitting diodes, and more particularly, to a light emitting diode whose light emitting efficiency is improved by reducing total internal reflectivity in an interface where a refractive index is changed, and a method for manufacturing the same.

2. Description of the Related Art

In a light emitting diode, light is produced by combination of electrons and holes at a p-n junction region of an interface between a p-semiconductor layer and an n-semiconductor layer. The light emission is spontaneous and has no specific direction. Accordingly, the light is emitted in all directions. A part of the light emitted is absorbed by the light emitting diode due to defects of the semiconductor layer. Therefore, the light emitted at right angles to the p-n junction region is less intense than the light emitted along the interface of the p-n junction region.

FIG. 1 shows a conventional light emitting diode. Referring to FIG. 1, an n-type compound semiconductor layer 12 is formed on a substrate 10. A certain region of the n-type compound semiconductor layer 12 protrudes upward to a predetermined height above the surface of the remaining region of the n-type compound semiconductor layer 12. Therefore, there is a step between the certain region and the remaining region of the surface of the n-type compound semiconductor layer 12. On the surface of the protruded region of the n-type compound semiconductor layer 12, an active layer 14 from which light is emitted and a p-type compound semiconductor layer 16 are sequentially formed. A p-type electrode 18 is formed on a certain region of the p-type compound semiconductor layer 16, and an n-type electrode 20 is formed on a certain portion of the non-protruded region of the n-type compound semiconductor region 12.

In the conventional light emitting diode, since the refractive index of the active layer 14 is greater than the refractive index of air around the light emitting diode, the light emitted from the active layer 14 is reflected from an interface of the active layer 14 back into the active layer 14. This reduces the light emitting efficiency of the conventional light emitting diode.

In order to improve the light emitting efficiency, many methods have been developed. For example, a surface from which light is emitted is inclined, or the refractive index of the active layer 14 is made to decrease toward the interface. However, such methods require additional processes which complicate the overall manufacturing process and thus they are not economical.

### SUMMARY OF THE INVENTION

The present invention provides a light emitting diode which is capable of improving a light emitting efficiency by reducing an internal reflection.

The present invention also provides a method of fabricating the light emitting diode.

According to an aspect of the present invention, there is provided a light emitting diode comprising a substrate, an n-type compound semiconductor layer which is formed on the substrate, an active layer which is formed on the n-type compound semiconductor layer, a p-type compound semiconductor layer which is formed on the active layer, an n-type electrode which contacts the n-type compound semiconductor layer, and a p-type electrode which contacts the p-type compound semiconductor layer, wherein a surface of the active layer from which the light is emitted is a continuous curved surface.

Preferably, the continuous curved surface is a waveform having a period and a depth. Preferably, the ratio of the period to the depth is 5 to 1.

A certain region of the n-type compound semiconductor layer protrudes to a predetermined thickness.

The active layer and the p-type compound semiconductor layer are sequentially deposited on the protruded region of the n-type compound semiconductor layer.

The shape of the surface of the active layer expands to the protruded region of the n-type compound semiconductor layer and to the p-type compound semiconductor layer.

According to another aspect of the present invention, there is provided a method of fabricating a light emitting diode wherein an n-type compound semiconductor layer, a compound semiconductor layer to be used as an active layer, and a p-type compound semiconductor layer are sequentially formed on a substrate and are patterned inversely until the n-type compound semiconductor layer is removed to a predetermined thickness, and an n-type electrode and a p-type electrode are formed on the patterned n-type compound semiconductor layer and the patterned p-type compound semiconductor layer respectively, patterning further comprising, forming a photosensitive film pattern having a circumference of a continuous curved surface on a certain region of the p-type compound semiconductor layer, etching the entire surface of the p-type compound semiconductor by using the photosensitive film pattern as an etch mask until the n-type compound semiconductor layer is removed to a predetermined thickness, and removing the photosensitive film pattern.

The continuous curved surface of the photosensitive film pattern is formed in a waveform having a predetermined period and a predetermined depth. The ratio of the period to the depth is 5 to 1.

According to the present invention, the amount of light totally reflected into an active layer from the surface of the active layer can be reduced. Thus, the light emission rate of the active layer can be much higher than that of an active layer in the conventional light emitting diode. As a result, the amount of light which is measured to be emitted from the light emitting diode increases, and the light is uniformly emitted in all directions. In addition, the method of the present invention is advantageous in that it is not necessary to add a separate process for forming the wave shape of the active layer.

### BRIEF DESCRIPTION OF THE DRAWINGS

The above and other features and advantages of the present invention will become more apparent by describing in detail exemplary embodiments thereof with reference to the attached drawings in which:

FIG. 1 is a perspective view of a conventional light emitting diode;

FIG. 2 is a perspective view of a light emitting diode having a high efficiency according to an embodiment of the present invention;

FIG. 3 is a cross-sectional view showing an unevenness part of a stripe type of the light emitting diode of FIG. 2;

FIG. 4 is a flowchart of a method of fabricating the light emitting diode of FIG. 2.

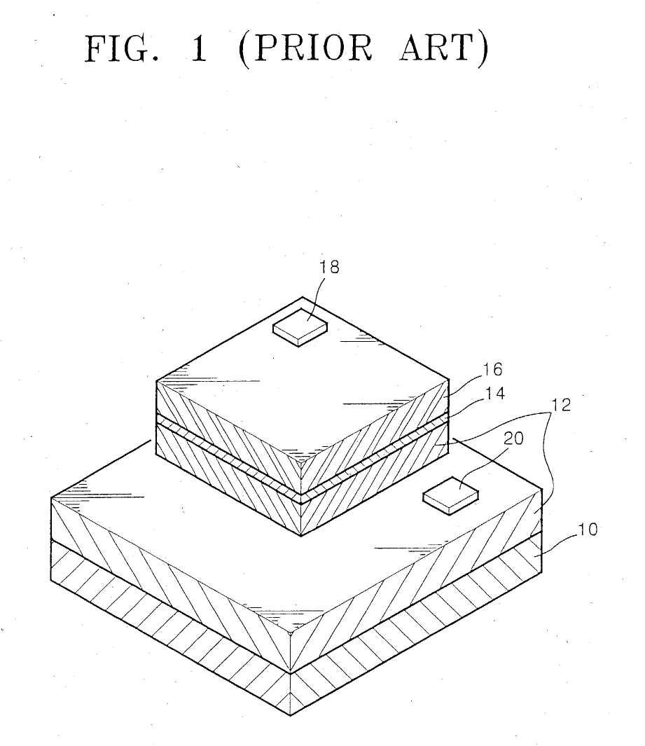

### DETAILED DESCRIPTION OF THE INVENTION

The present invention will now be described more fully with reference to the accompanying drawings, in which preferred embodiments of the invention are shown. The thickness of layers and regions is exaggerated for clarity.

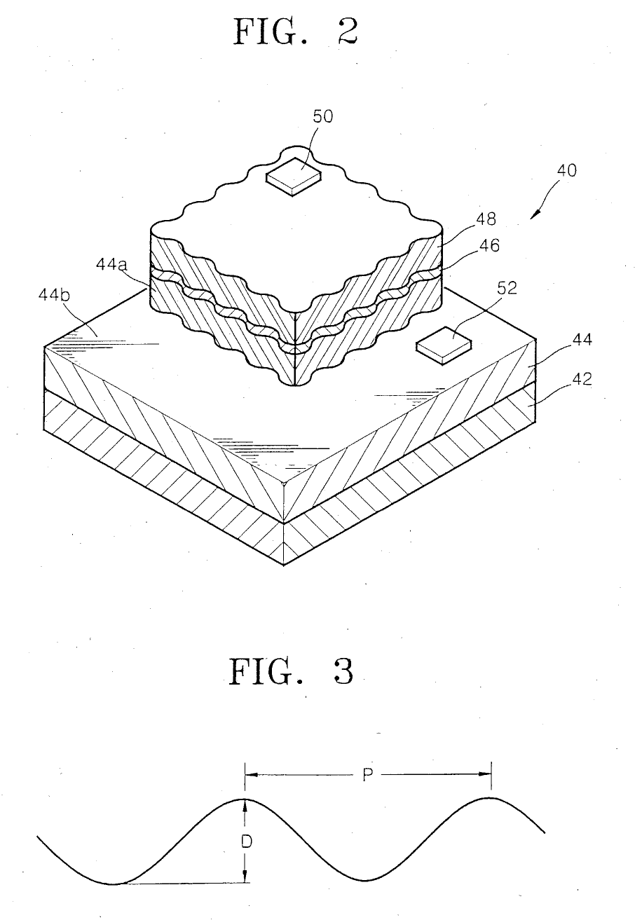

Referring to FIG. 2, a light emitting diode 40 according to an embodiment of the present invention includes a plurality of components formed on a substrate 42. Specifically, an n-type compound semiconductor layer 44 is formed on the substrate 42. A certain region of the n-type compound semiconductor layer 44 protrudes to a predetermined height above the surface of the remaining region of the n-type compound semiconductor layer 44. Thus, there is a step between the protruded region 44a and the remaining region 44b of the n-type compound semiconductor layer 44. On the protruded region 44a, preferably, on the entire surface of the protruded region 44a, an active layer 46 and a p-type compound semiconductor layer 48 are sequentially formed. A p-type electrode 50 is formed on a certain portion of the p-type compound semiconductor layer 48, and an n-type electrode 52 is formed on a certain portion of the non-protruded region 44b of the n-type compound semiconductor layer 44.

In the composition as described above, the active layer 46 and a material layer, i.e., air, that surrounds the active layer 46, have different optical refractive indices from each other. Thus, some of the light emitted from the active layer 46 is reflected from an interface between the active layer 46 and the material layer back into the active layer 46. Since the total amount of light emitted from the light emitting diode 40 decreases as the light reflected from the interface increases, brightness of the light emitting diode 40 decreases. If the light reflected from the interface is absorbed into a semiconductor material which composes the active layer 46, the absorbed light is, for the most part, changed into heat, and thus the temperature of the light emitting diode 40 increases, degrading its operation efficiency.

The present inventors assumed that the degradation mainly relates to the shape of the interface which contacts the material layer surrounding the active layer 46, i.e., the shape of the circumference of the active layer 46. Thus, the present inventor executes simulations of cases when the circumference of the active layer 46 is formed in an unevenness (hereinafter, this case will be referred to as a first case), and when the circumference of the active layer 46 is flat like the conventional light emitting diode (hereinafter, this case will be referred to as the second case). In the simulations, an optimal circumference shape is found through numerical formulas with respect to changes in light emitting efficiency according to the first and second cases. In particular, in the first case, the optimal circumference shape is found by a numerical formula with respect to change in the light emitting efficiency according to a period P and a depth D of the circumference of the active layer 46.

In the first case, the present inventor makes the circumference of the active layer 46 in a continuous waveform, as shown in FIG. 2, instead of in a simple unevenness shape. FIG. 3 shows a part of the circumference of the active layer 46 in a waveform, viewed from the upper direction of the active layer 46. The waveform of the circumference of the active layer 46 can be expanded upward or downward. For example, it can be extended downward to the circumference of the protruded region 44a of the n-type compound semiconductor layer 44 and upward to the circumference of the p-type compound semiconductor layer 48.

The waveform of the circumference of the active layer 46 can be formed by changing a design of a mask used in dry etching for forming of the light emitting diode 40. That is, the circumference of the active layer 46, the protruded region 44a of the n-type compound semiconductor layer 44, and the p-type compound semiconductor layer 48 can be formed in a waveform by using a mask whose circumference is designed in a waveform for dry etching.

More specifically, because the mask is a photosensitive film pattern formed on a certain region of the p-type compound semiconductor layer, the mask can be formed by forming a photosensitive film pattern so that is side becomes a continuous curved surface in a process for forming the photosensitive film pattern in which a photosensitive film is formed on the p-type compound semiconductor layer and it is patterned. Here, it is preferable that the circumference of the photosensitive film pattern is formed to be a continuous curved surface which satisfies a simulation result described below. After forming the mask, i.e., the photosensitive film pattern, the p-type compound semiconductor layer and the active layer are sequentially etched by using the photosensitive pattern as an etch mask, and a predetermined thickness of the n-type compound semiconductor layer is removed. Then, by removing the photosensitive film pattern, the protruded region 44a of the n-type compound semiconductor layer 44, the active layer 46 and the p-type compound semiconductor layer 48 are formed as shown in FIG. 2.

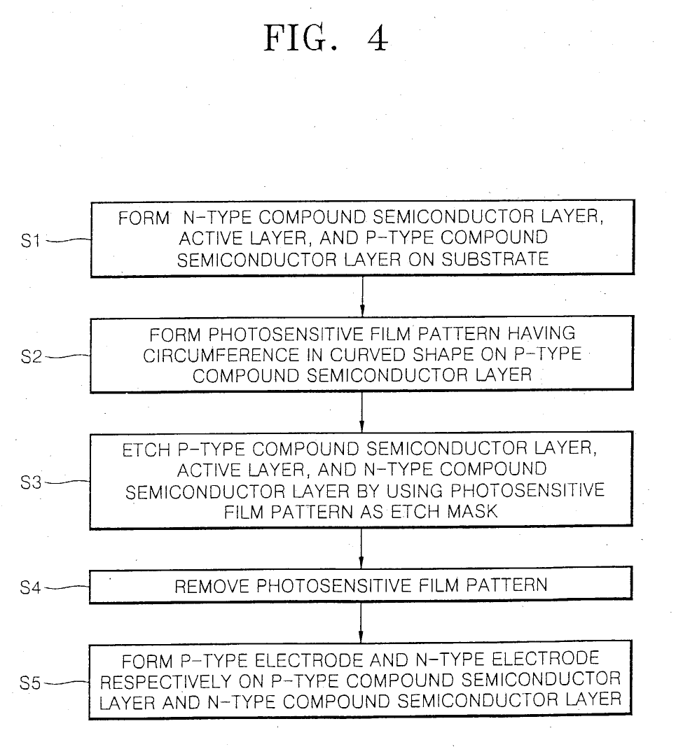

Referring to FIG. 4, the method of fabricating the light emitting diode can be described as follows.

In a first step (S1), the n-type compound semiconductor layer, the compound semiconductor layer to be used as the active layer, and the p-type compound semiconductor layer are sequentially formed on the substrate.

In a second step (S2), the photosensitive film pattern having a circumference with a curved surface, preferably a continuous curved surface is formed on the p-type compound semiconductor layer.

In a third step (S3), the p-type compound semiconductor layer, the compound semiconductor layer to be used as the active layer, and the n-type compound semiconductor layer are sequentially etched by using the photosensitive pattern as an etch mask. Here, the etching continues until the n-type compound semiconductor layer is etched to a predetermined thickness.

In a fourth step (S4), the photosensitive film pattern is removed. In a fifth step (S5), the p-type electrode and the n-type electrode are formed on the p-type compound semiconductor layer whose circumference is patterned in a curved surface by the etching and on the n-type compound semiconductor layer in which the side of the protruded region is patterned in a curved surface, respectively.

The results of the simulations for the first and the second cases are as follows.

When the circumference of the active layer 46 is formed in a waveform like a harmonic function shape, emission of light from the active layer 46 increases. In particular, if the light emitting surface of the active layer 46 is formed in a waveform as shown in FIG. 3, the internal reflectivity of the active layer 46 is lowest when a period P and an depth D of the waveform have a ratio of 1 to 1 or more, for example, 2 to 1, and most preferably, a ratio of 5 to 1 (for example, the period P is 20 μm, and the depth D is 4 μm.). This means that a light emitting rate of the light emitting diode 40 is highest in the preferable ratios of the period P and the depth D.

In the simulations, when the light emitting surface of the active layer 46 is a waveform whose the ratio of the period P and the depth D is 5 to 1, light emission from the active layer 46 increases by 9%. In addition, the light emitted from the light emitting diode is widely distributed twice of the second case where the circumference of the active layer 46 is flat.

Since the light emitting surface of the active layer by the present invention is formed in a waveform, the amount of light reflected toward the inside of the active layer at the surface of the active layer by an internal total reflection can be reduced, and thus light emission from the active layer increases than that of the conventional technology. Accordingly, the total amount of light measured in the outside increases, and also the uniformity of the emitted light increases. In addition, a separate process is not needed for forming the waveform of the active layer, because the waveform is formed by designing the circumference of the mask used in a conventional optical device manufacturing process to be a waveform, and etching the active layer by using the mask.

While the present invention has been particularly shown and described with reference to exemplary embodiments thereof, it will be understood by those of ordinary skill in the art that various changes in form and details may be made therein without departing from the spirit and scope of the present invention as defined by the following claims. For example, those of ordinary skill in the art can apply the spirit of the present invention to a light emitting diode of a ridge type. In addition, they can apply the spirit of the present invention to a light emitting diode in which the n-type electrode is formed on the bottom surface of the substrate.

What is claimed is:

1. A light emitting diode comprising:
a substrate;
an n-type compound semiconductor layer which is formed on the substrate;
an active layer which is formed on the n-type compound semiconductor layer;
a p-type compound semiconductor layer which is formed on the active layer;
an n-type electrode which contacts the n-type compound semiconductor layer; and
a p-type electrode which contacts the p-type compound semiconductor layer,
wherein a surface of the active layer from which the light is emitted is a continuous curved surface.

2. The light emitting diode of claim 1, wherein the continuous curved surface is a waveform having a period and a depth.

3. The light emitting diode of claim 2, wherein the ratio of the period to the depth is 5 to 1.

4. The light emitting diode of claim 1, wherein a certain region of the n-type compound semiconductor layer protrudes to a predetermined thickness, and the active layer and the p-type compound semiconductor layer are sequentially deposited on the protruded region of the n-type compound semiconductor layer.

5. The light emitting diode of claim 4, wherein the shape of the surface of the active layer expands to the protruded region of the n-type compound semiconductor layer and to the p-type compound semiconductor layer.

6. A method of fabricating a light emitting diode wherein an n-type compound semiconductor layer, a compound semiconductor layer to be used as an active layer, and a p-type compound semiconductor layer are sequentially formed on a substrate and are patterned inversely until the n-type compound semiconductor layer is removed to a predetermined thickness, and an n-type electrode and a p-type electrode are formed on the patterned n-type compound semiconductor layer and the patterned p-type compound semiconductor layer respectively, patterning further comprising:
forming a photosensitive film pattern having a circumference of a continuous curved surface on a certain region of the p-type compound semiconductor layer;
etching the entire surface of the p-type compound semiconductor by using the photosensitive film pattern as an etch mask until the n-type compound semiconductor layer is removed to a predetermined thickness; and
removing the photosensitive film pattern.

7. The method of claim 6, wherein the continuous curved surface of the photosensitive film pattern is formed in a waveform having a predetermined period and a predetermined depth.

8. The method of claim 7, wherein the ratio of the period to the depth is 5 to 1.
